(19) United States
(12) Patent Application Publication
(10) Pub. No.: US 2010/0117536 A1
(43) Pub. Date: May 13, 2010

(54) Control Circuit and Method for Controlling Large-Scale Semiconductor Light Sources

(76) Inventors: Ralf Hying, Munchen (DE); Peter Niedermeier, Munchen (DE)

Correspondence Address: COHEN, PONTANI, LIEBERMAN & PAVANE LLP, 551 FIFTH AVENUE, SUITE 1210, NEW YORK, NY, 10176, US

(21) Appl. No.: 12/525,054

(22) PCT Filed: Jan. 15, 2008
(86) PCT No.: PCT/EP2008/050391

§ 371 Date: Jul. 29, 2009

(30) Foreign Application Priority Data
Jan. 29, 2007 (DE) 10 2007 004 393.9

(51) Int. Cl. H05B 37/02; H01L 27/15

(52) U.S. Cl. 315/35

(57) ABSTRACT

A drive circuit for driving semiconductor light sources having one or more semiconductor light sources applied to a circuit mount, wherein the drive circuit for driving semiconductor light sources is also applied to the circuit mount and can generate pulses with a rise time of less than 3 μs.

### TECHNICAL FIELD

The invention relates to a spatial circuit arrangement for driving large-area semiconductor light sources. The invention also relates to a method for effectively driving large-area semiconductor light sources.

### PRIOR ART

LED modules are nowadays usually provided with a comparatively small proportion of driver electronics. In order to save costs and use synergies, the majority of the drive electronics are combined in an external operating device, and only a module coding and a few operationally advantageous filters are located on the LED module. This has the advantage that an operating device can be used for a plurality of different LED modules. Since the operating device cannot always be connected directly to the LED module in spatial terms, the lines between the drive electronics and the LED module are often comparatively long. This still does not present a relatively major problem for normal semiconductor light sources, since the latter are often operated with a constant current. However, problems of various sorts occur in the case of lighting solutions requiring the semiconductor light sources to be switched on and off quickly. The long supply leads constitute a parasitic capacitance and inductance that have a disadvantageous effect on the operational performance of the overall system. As soon as the operating electronics requires information relating to the temperature of the light emitting diodes, there is a need for an additional temperature sensor on the LED module, and this increases the outlay on wiring and costs. The electromagnetic interfering radiation, which is caused primarily by the long supply leads acting as radiating antenna, is a serious problem for pulsed operating methods.

### OBJECT

The object of the present invention is therefore to develop the spatial arrangement of the circuit arrangement further such that the above-named disadvantages are avoided.

### SUMMARY OF THE INVENTION

This is achieved by virtue of the fact that the associated drive circuit for the light emitting diodes is arranged very close to them in order to be able to carry out an efficient operating method. The invention is preferably used for so-called high intensity light emitting diodes, which are light emitting diodes that, by contrast with conventional light emitting diodes, have a substantially larger luminous surface and a greatly increased current consumption.

Modern high intensity light emitting diodes are highly sophisticated light sources that must be operated using a special method in order to meet all the demands placed on modern illumination and projection technology.

Especially in the field of projection technology, highly developed operating methods are used to meet the demands placed on an enhanced image quality. The high intensity light emitting diodes are driven with signals (pulses) that have very steep edges and are sometimes also very short (pulse rise time less than or equal to 3 μs, pulse lengths down to 4 μs). Located between these pulses are pulse pauses of greater or lesser length in which the current vanishes. The entire sequence of the pulses and pulse pauses one after another is referred to here as pulse train. The signal sequences must likewise have a very large dynamic range; thus, it can happen that the output current in a pulse must be switched from a maximum current value to a current value that corresponds to 1% of the maximum value. Such a pulse is then subdivided into a plurality of pulse segments. The influences of the supply leads must be minimized in order to be able to implement such signal sequences.

This likewise holds true for the primary control characteristic. The high intensity light emitting diodes are operated using a high resolution (>=8 bit resolution) current control. This is required in order to ensure a uniform life performance of the various high intensity light emitting diodes on the module. When current supply leads are kept short and there is a short feedback path, the controller operates much more stably and is less susceptible to disturbances.

In order to create these necessary preconditions, the driver circuits for the high intensity light emitting diodes are therefore integrated directly on the module in accordance with the invention. The connection to the host system is performed solely via the power supply and a digital interface for the purpose of setting the current levels and the timing.

The driver circuits are advantageously arranged such that the current-carrying paths to the high intensity light emitting diodes assigned to them are as short as possible.

In the case of multicolor applications, such as are used in projection, the high intensity light emitting diodes and the associated driver circuits can be integrated for all colors on one module.

In the case of very powerful modules, it can be advantageous to use one or more system-wide pre-controllers. The pre-controllers supply an adapted power with a voltage that is only slightly above the voltage of the high intensity light emitting diodes. The driver circuits can thus operate efficiently and the power loss is minimized. In the case of multicolor modules, it is possible, for example, to use a single pre-controller for each color.

### BRIEF DESCRIPTION OF THE DRAWING(S)

FIG. 1 shows a section through a LED module on an aluminum-core printed circuit board according to the prior art,

FIG. 2 shows a section through an inventive LED module with high intensity light emitting diodes and associated driver circuits on an aluminum-core printed circuit board,

FIG. 3 shows a plan view of the inventive LED module, and

FIG. 4 shows an exemplary pulse sequence of a preferred embodiment.

### PREFERRED DESIGN OF THE INVENTION

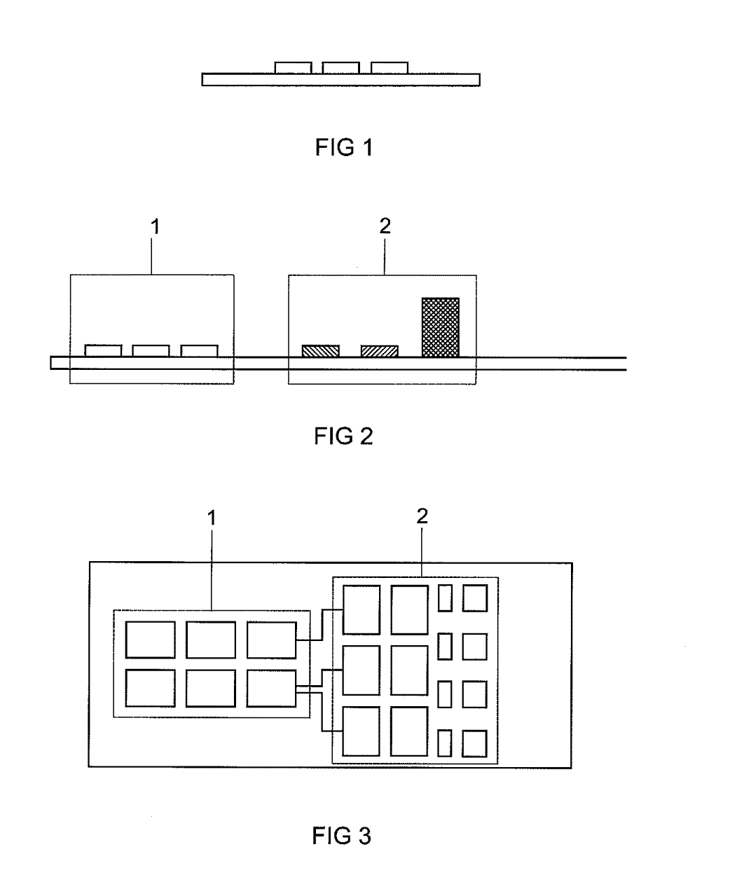

FIG. 1 shows the section through a known LED module according to the prior art. The high intensity light emitting diodes are mounted on an aluminum-core printed circuit board in order to ensure good heat dissipation. An aluminum-core printed circuit board chiefly comprises an aluminum plate onto which a thin printed circuit board is laminated. Therefore, it is also possible to apply any other material that is a good conductor of heat instead of aluminum. In a standard method, the components are soldered onto this printed circuit board. Owing to the fact that the printed circuit board is very thin, and that the main mass of the module consists of aluminum or another material that is a good conductor of heat, a very good heat dissipation is achieved.

FIG. 2 shows an inventive LED module in the case of which the associated drive electronics (2) is also accommodated on the printed circuit board in addition to the high intensity light emitting diodes (1). This has a plurality of advantages:
the current paths from the drive electronics to the high intensity light emitting diodes are very short, and so it is possible to implement good control properties and efficient operating methods.
The measurement can be executed more accurately for the current control, since the parasitic effects are minimized by the short supply leads.
High intensity light emitting diodes and driver circuits are subject to the same temperature, and so it is essentially more easy to compensate temperature effects in the driver circuit and to avoid overheating of the light emitting diodes.
The electromagnetic compatibility becomes problematic owing to the pulsed driving and the high edge steepnesses. The shortness of the current paths additionally helps to minimize the electromagnetic emission.

FIG. 3 shows a plan view of the inventive module. The driver circuits (2) are placed at a certain minimum spacing from the high intensity light emitting diodes (1) in order not to obstruct optical devices that are placed over the high intensity light emitting diodes (1). The length of the current paths to the high intensity light emitting diodes (1) is minimized by the direct connection.

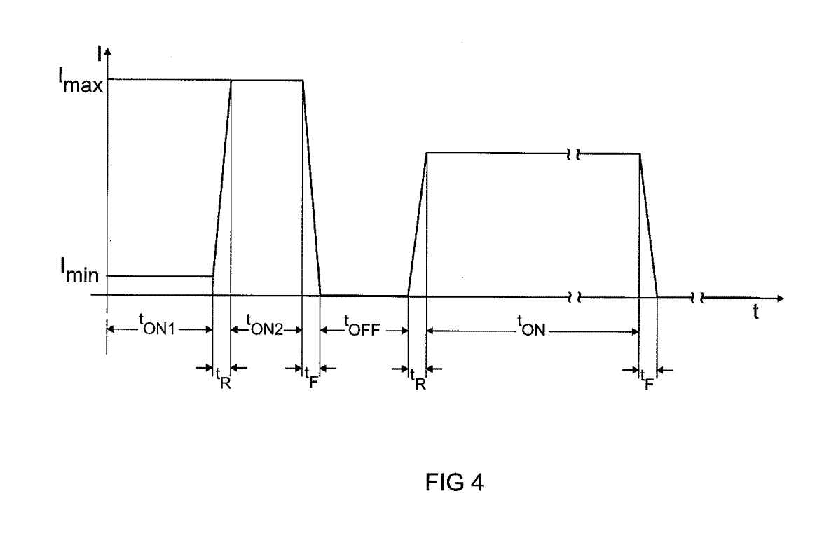

Finally, FIG. 4 shows an exemplary pulse sequence of the preferred embodiment. The driver circuit can constitute a maximum current Iₘₐₓ and a minimum current Iₘᵢₙ. The edge rise and fall times are denoted by t_{R} and t_{F}, respectively. The maximum edge steepness is displayed in the first pulse and is represented by the time period t_{F} in which the high intensity light emitting diode current moves from maximum current to zero. t_{OFF} stands for the time duration between two pulses, t_{ON} normally stands for the length of the pulse minus the duration of the edge rise. However, it can also happen that a pulse is composed of various current values, as illustrated in the first pulse in FIG. 4. Here, the pulse consists of a first pulse segment with the on time t_{ON1} with the current I_{Min} and a second pulse segment with the on time t_{ON2} with the current I_{Max}.

The preferred embodiment of the drive circuit comprises an in-phase regulator that is switched on and off with the desired pulse train. The in-phase regulator is driven by means of a fast logic and can thus quickly change and set the current in a pulse. In the case of modules of higher power, it is also possible to use a pre-controller such that the power loss in the in-phase regulator is minimized.

A switched-mode regulator would also be conceivable as an alternative, but switched-mode regulators with the abovementioned reaction times are complicated and expensive in design.

1. A drive circuit for driving semiconductor light sources having one or more semiconductor light sources applied to a circuit mount, wherein the drive circuit for driving semiconductor light sources is also applied to the circuit mount and can generate pulses with a rise time of less than 3 μs.

2. The drive circuit as claimed in claim 1, wherein the drive circuit is adapted to generate pulses with a pulse duration of 4 μs-150 ms.

3. The drive circuit as claimed in claim 1, wherein the drive circuit is adapted to control the current intensity in a pulse and can set it to different values.

4. The drive circuit as claimed in claim 3, wherein the drive circuit is adapted to control the current intensity in a pulse from 1% of the current intensity to 100% of the current intensity.

5. The drive circuit as claimed in claim 1, wherein the thermal conductivity of the circuit mount is so high that the temperature of the semiconductor light sources in the drive circuit can be measured.

6. The drive circuit as claimed in claim 1, wherein the circuit mount comprises an aluminum-core printed circuit board.

7. The drive circuit as claimed in claim 1, wherein the circuit mount comprises a copper-core printed circuit board.

8. The drive circuit as claimed in claim 1, wherein the circuit mount comprises a ceramic substrate.

9. The drive circuit as claimed in claim 1, wherein the circuit mount is suitable for holding optical elements for the semiconductor light sources.

10. The drive circuit as claimed in claim 1, wherein the drive circuit includes a linear controller that is switched on and off in time with pulse trains that comprise consecutive pulses and pulse pauses.

11. The drive circuit as claimed in claim 1, wherein the drive circuit includes a clocked switched-mode converter that can generate the pulse trains.

12. A method for operating semiconductor light sources that are arranged severally on a circuit mount, the drive circuits for the semiconductor light sources also being arranged on the printed circuit board, wherein the semiconductor light sources are operated with consecutive pulses, it being possible for the duration of the pulses to differ and for the pause between two pulses to differ, and for the current intensity in a pulse to be controlled to different current values.

13. The method for operating semiconductor light sources as claimed in claim 12, wherein the current intensity in a pulse can be controlled from 1% of the current intensity to 100% of the current intensity.
